(19) United States
(12) Patent Application Publication
(10) Pub. No.: US 2024/0222213 A1
(43) Pub. Date: Jul. 4, 2024

(54) EMBEDDED SILICON-BASED DEVICE COMPONENTS IN A THICK CORE SUBSTRATE OF AN INTEGRATED CIRCUIT PACKAGE

(71) Applicant: NVIDIA Corporation, Santa Clara, CA (US)

(72) Inventors: Ronilo Boja, Santa Clara, CA (US); Padam Jain, Santa Clara, CA (US)

(21) Appl. No.: 18/091,943

(22) Filed: Dec. 30, 2022

(51) Int. Cl. H01L 23/31; H01L 21/683; H01L 21/768; H01L 21/786; H01L 23/00; H01L 23/36; H01L 23/498; H01L 25/10

(52) U.S. Cl. CPC H01L 23/3121; H01L 21/6835; H01L 21/76877; H01L 21/786; H01L 23/36; H01L 23/49827; H01L 24/08; H01L 24/16; H01L 24/94; H01L 25/105; H01L 2224/08113; H01L 2224/16146; H01L 2224/94; H01L 2225/1035; H01L 2225/1058; H01L 2924/15153

(57) ABSTRACT

An integrated circuit package including a package substrate including a monolithic core, the monolithic core having a first substrate side, a second substrate side opposite the first substrate side, a thickness in a range from 800 to 2000 microns and a through-cavity that passes through the first and second substrate sides. The package includes a device module, the device module having a first module side and a second module side opposite the first module side. The device module is embedded in the through-cavity, the first module side is aligned with the first substrate side, the second module side is aligned with the second substrate side, and the device module includes one or more silicon-based passive or silicon-based active device component. A method of manufacture of the integrated circuit package is also disclosed.

### TECHNICAL FIELD

This application is directed, in general, to integrated circuit (IC) operations and packaging, and in particular, IC packages having a thick core substrate and silicon-based device components embedded therein, and, methods of manufacturing the IC package.

### BACKGROUND

It is sometimes desirable to place silicon-based device components (e.g., passive device components such as capacitors, resistors and inductors or active device components such as transistors formed in silicon wafers) as close as possible to a chip (e.g., a silicon die) to improve electrical performance. One way to accomplish this is to embed the device component into a package substrate that the chip is located on. Current embedding methods embed the device component in package substrates having a thin core or multi-thin cores (e.g., individual core thicknesses of 250 microns).

Silicon wafers of a particular diameter are typically grown to be thick enough to support its own weight without cracking during handling and dicing. E.g., silicon wafers having a diameter of 150, 200 or 300 mm are often grown to have thicknesses of 675, 725 or 775 microns, respectively. Although 450 mm diameter (e.g., 925 micron thick) silicon wafers are under investigation, the development of large scale cost-effective commercial availability is ongoing, since, e.g., a large-scale fabrication facility (fab) for 450 mm diameter silicon wafers could cost over one billion dollars. Thus, a silicon-based device component formed using currently reliable commercially-available silicon wafer technology (e.g., 300 mm or smaller diameters) typically have a 775 micron or smaller thickness.

### SUMMARY

One aspect is an integrated circuit package. The package includes a package substrate including a monolithic core, the monolithic core having a first substrate side, a second substrate side opposite the first substrate side, a thickness in a range from 800 to 2000 microns and a through-cavity that passes through the first and second substrate sides. The package includes a device module, the device module having a first module side and a second module side opposite the first module side. The device module is embedded in the through-cavity, the first module side is aligned with the first substrate side, the second module side is aligned with the second substrate side, and the device module includes one or more silicon-based passive or silicon-based active device component.

Another aspect is a method of manufacturing an integrated circuit package including providing a monolithic core, the monolithic core having a first substrate side, a second substrate side opposite the first substrate side, a thickness in a range from 800 to 2000 microns, forming a through-cavity in the monolithic core, the through-cavity passing through the first and second substrate sides, providing a device module, the device module having a first module side and a second module side opposite the first module side, and embedding the device module in the through-cavity, where the first module side is aligned with the first substrate side, the second module side is aligned with the second substrate side, and the device module includes one or more silicon-based passive or silicon-based active device component.

### BRIEF DESCRIPTION

Reference is now made to the following descriptions taken in conjunction with the accompanying drawings, in which:

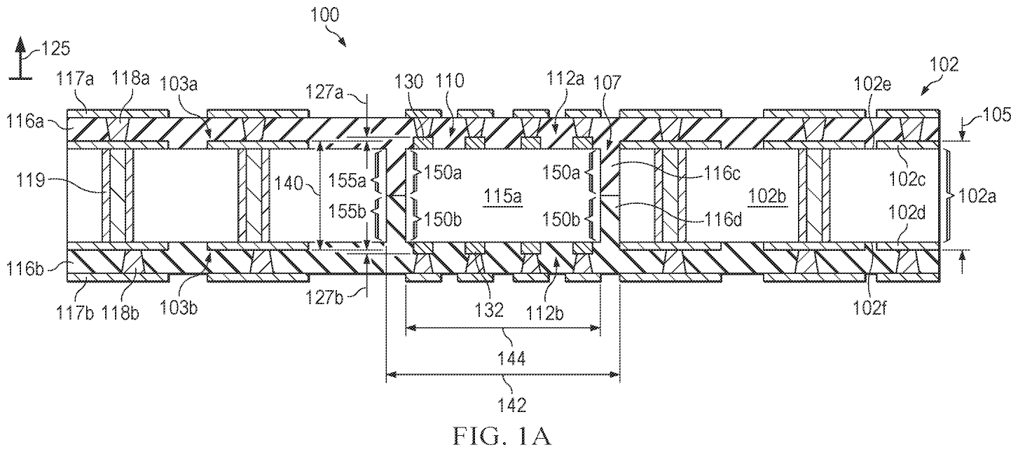

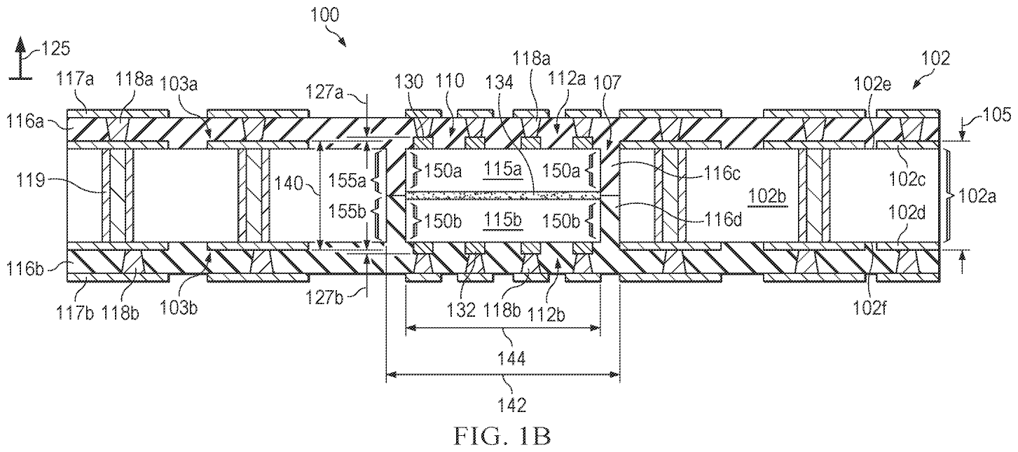

FIG. 1A presents a cross-sectional view of an example embodiment of an IC package of the disclosure;

FIG. 1B presents a cross-sectional view of another example embodiment of an IC package of the disclosure;

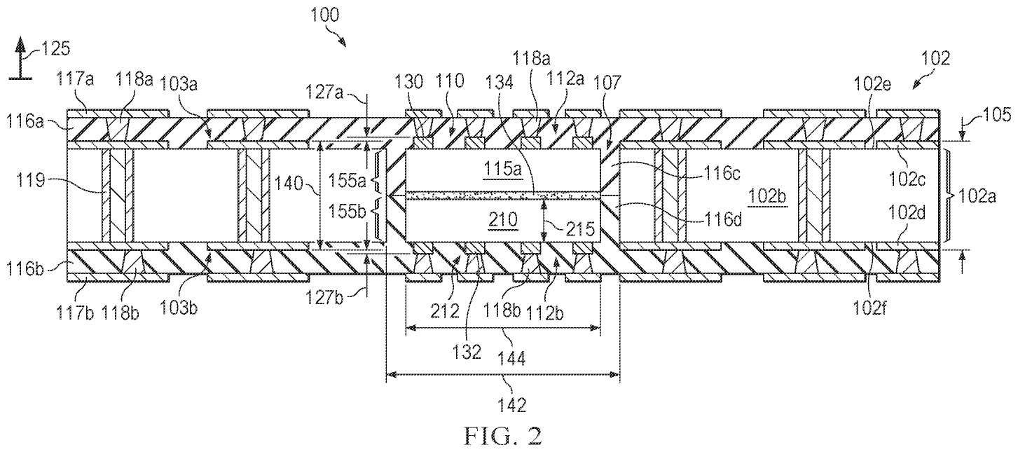

FIG. 2 presents a cross-sectional view of another example embodiment of an IC package of the disclosure;

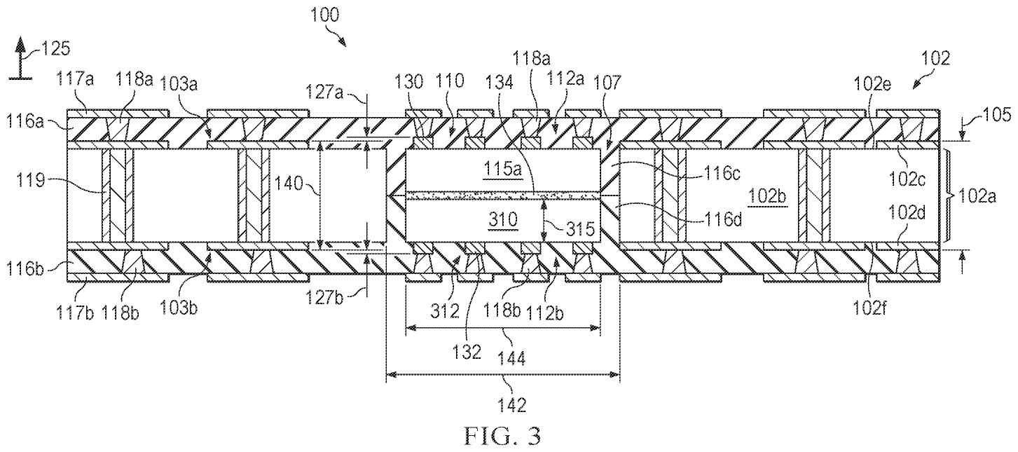

FIG. 3 presents a cross-sectional view of another example embodiment of an IC package of the disclosure;

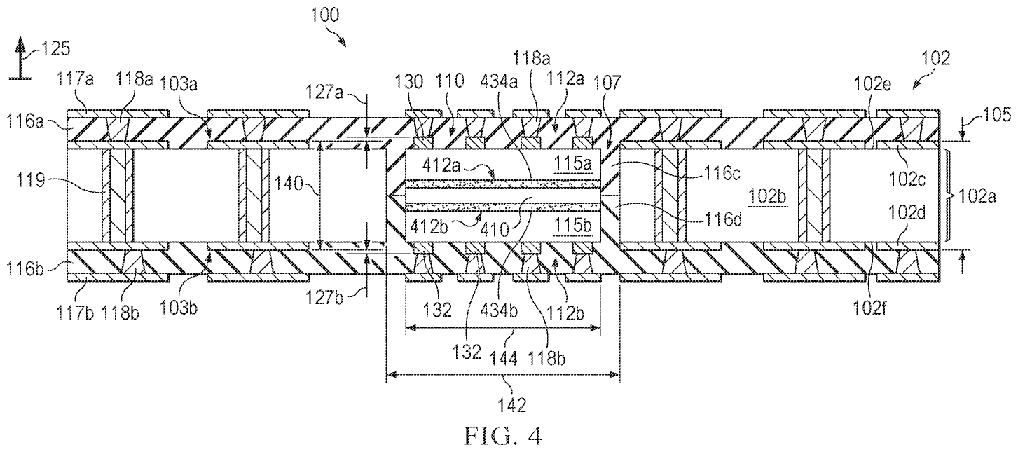

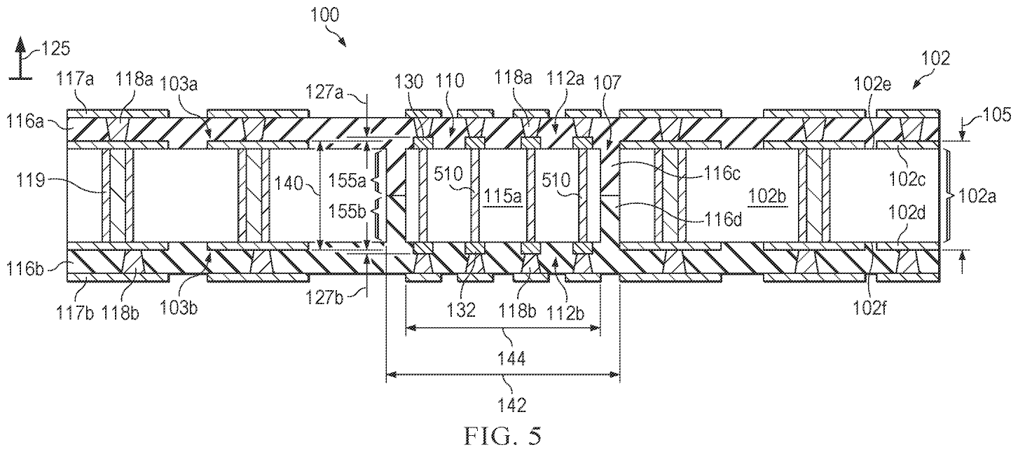

FIG. 4 presents a cross-sectional view of another example embodiment of an IC package of the disclosure;

FIG. 5 presents a cross-sectional view of another example embodiment of an IC package of the disclosure;

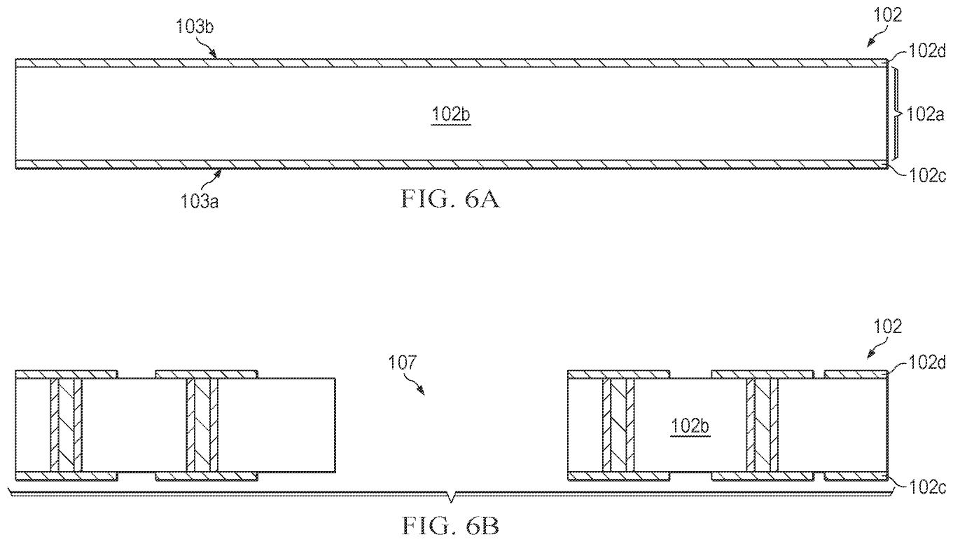

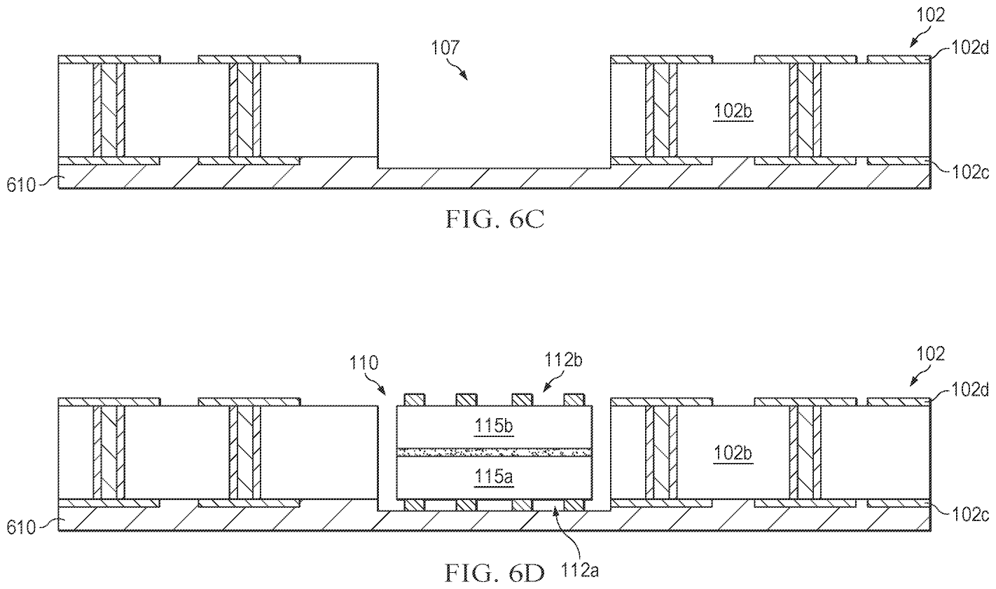

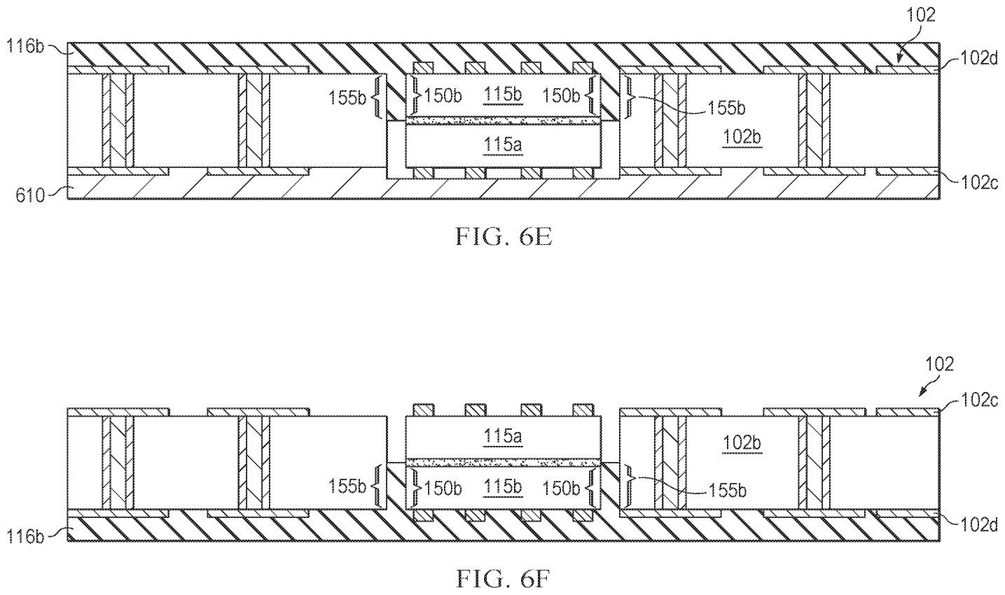

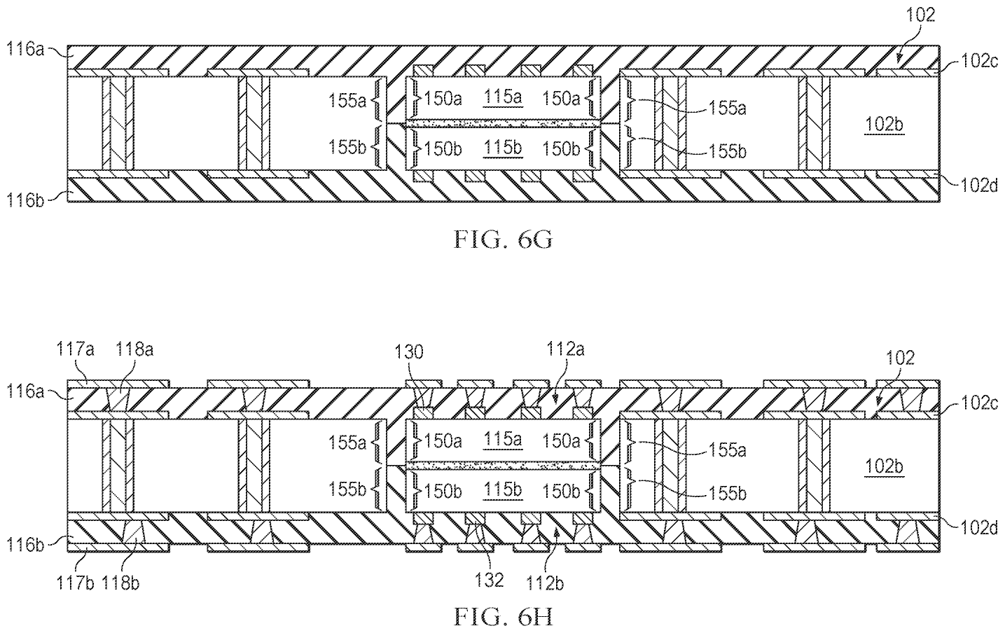

FIGS. 6A-6H present cross-sectional views of example IC packages, such as any of the example package embodiments disclosed in the context of FIGS. 1-5, at different stages of manufacture;

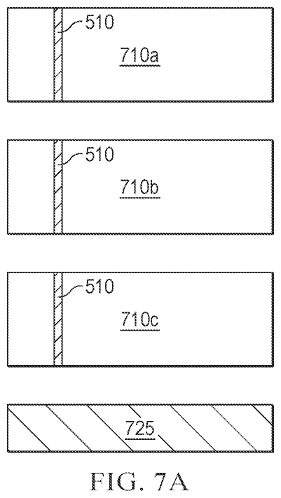

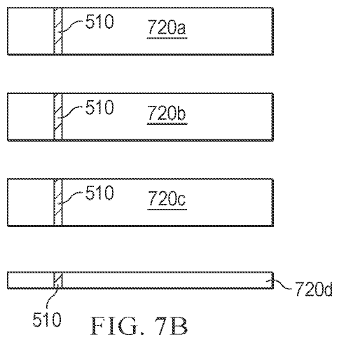

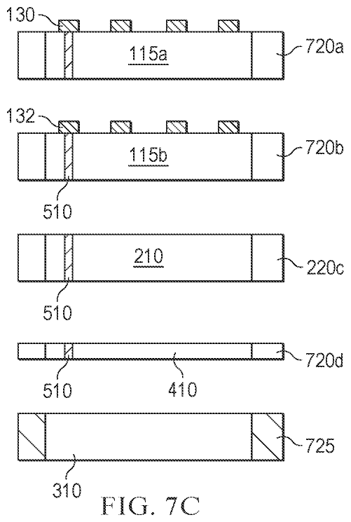

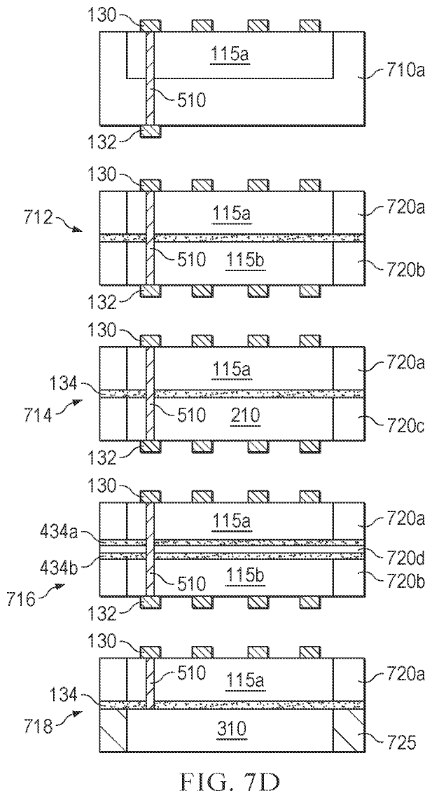

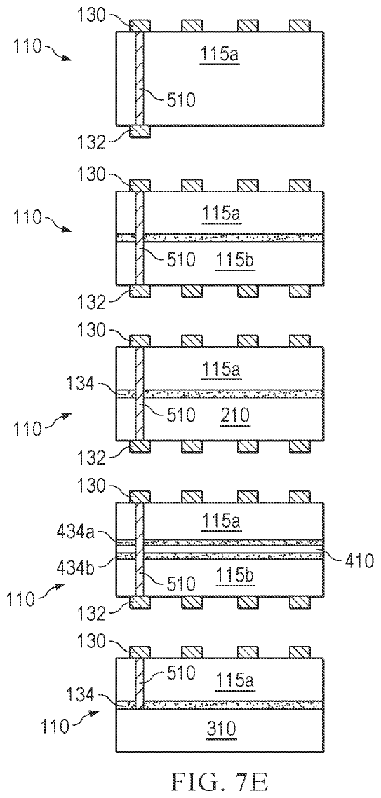

FIGS. 7A-7E present cross-sectional views of an example device module having one or more silicon-based device component, such as any of the example module embodiments disclosed in the context of FIGS. 1-5, at different stages of device formation as part of the manufacture of the IC package; and

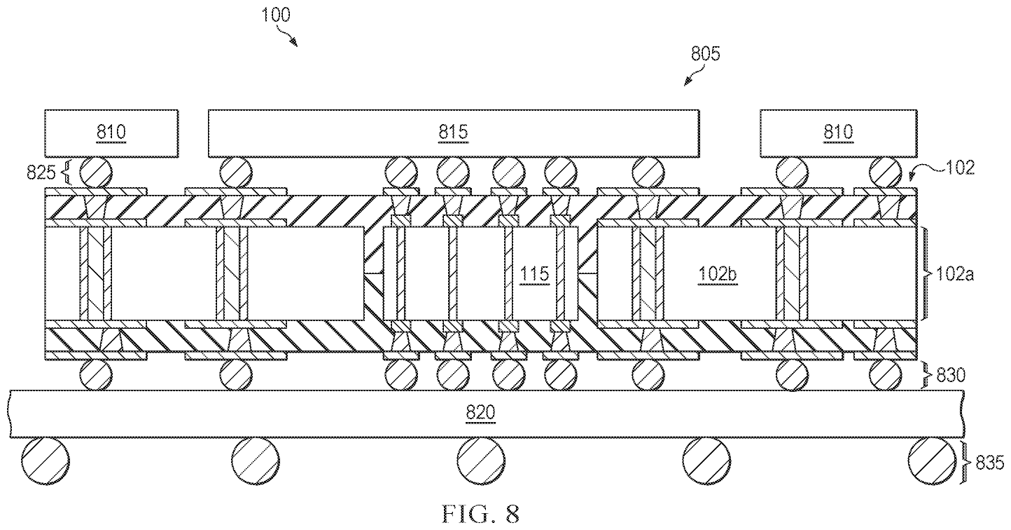

FIG. 8 presents another example embodiment of the IC package including any embodiments of the package substrate and device module discussed in the context of FIGS. 1-5 and made by the method disclosed in the context of FIGS. 6A-7E.

### DETAILED DESCRIPTION

Embodiments of the disclosure follow from our efforts to embed silicon-based device components in a package substrate having a thick core to address facilitate the use of package substrates having thicker cores. Such thick package substrates help mitigate mechanical warpage for package substrates having ever-larger areas (e.g., 70 by 70 mm or 4900 mm²; 80 by 80 mm or 6400 mm²) that accommodate increasingly complex system-on-chip (SoC) IC designs (e.g., Chip-on-Wafer-on-Substrate, CoWoS) carrying chiplets with multiple central processing units (CPU), graphic processing units (GPUs) and/or high bandwidth memory (HBM) thereon (e.g., chiplets areas of 50 by 50 mm or 2500 mm²; 60 by 60 mm or 3600 mm²).

Embedding a silicon-based device component in a package substrate composed of multi-layer thin cores is expensive and complex, and, can be problematic because the multiple copper layers on each of the thin core layers raises the coefficient of thermal expansion (CTE) of the package substrate, which in turn, can create significant warpage for the resulting package substrate with reduced reliability.

A solution to this problem, as further disclosed herein, is to provide a package substrate having single layer monolithic core instead of multi-layer thin cores. The use of such a monolithic core simplifies the manufacturing process and cost as compared to using a multilayer thin core of similar overall thickness. Additionally, such a monolithic core, having a single layer of copper on either side, has a lower CTE and is less prone to warpage than a multi-layer thin core of similar overall thickness.

However, a remaining problem with embedding a silicon-based device component in such a thick package substrate having a monolithic core is that silicon wafers thicknesses are limited to 775 microns, but, package substrate of larger target thicknesses are desired (e.g., 800 microns, 1 mm, 1.6 mm or 2 mm or values therebetween). As such, there is a mismatch in the thickness of the silicon-based device components versus the desired target thickness of the package substrate.

Our solution to this problem, as further disclosed herein, is to couple the silicon-based device component to another silicon-based device component (e.g., a back-to-back coupling), or, to a silicon dummy layer component, or, to a metal heat sink layer component, or combinations thereof, to provide a device module having an overall thickness that matches the desired target thickness of the package substrate. With appropriate adjustment of the thickness of these components, if needed, a wide range of device module thicknesses can be achieved to thereby match a wide range of package substrate thicknesses. Embodiments of the device module having back-to-back coupled device components can advantageously increase the component density per area of the package substrate, and the placement of the same type of component can double the device module's electrical property (e.g., doubling capacitance, inductance, resistance). Embodiments of the device module having metal-filled through-device vias can advantageously facilitate heat dissipation from device components and/or shorten or simply the routing to chiplets and/or further alter the device component's electrical properties.

One aspect of the disclosure is an integrated circuit package. FIGS. 1A-5 present cross-sectional view various embodiments of example IC packages 100 of the disclosure.

In some embodiments, the IC package can include at least a single silicon-based device component that spans the thickness of the core. For instance, for the IC package 100 illustrated in FIG. 1A, the package includes a package substrate 102 including a monolithic core 102a, the monolithic core having a first substrate side 103a, a second substrate side 103b opposite the first substrate side, a thickness 105 in a range from 800 to 2000 microns and a through-cavity 107 that passes through the first and second substrate sides 103a, 103b. The package also includes a device module 110. The device module has a first module side 112a and a second module side 112b opposite the first module side. The device module 110 is embedded in the through-cavity 107, the first module side 112a is aligned with the first substrate side 103a, the second module side 112b is aligned with the second substrate side 103b, and the device module 110 includes one or more silicon-based passive or silicon-based active device component 115a.

The term package substrate, as used herein, refers to a material layer positioned between a chip or chiplets (e.g., SoC) and a printed circuit board (PCB), in a stacked configuration, to provide connective routing structures (e.g., pads, lines and vias) between the chip, components of the device module and external devices, as well as provide mechanical support for the chip and the PCB. The package substrate includes a monolithic core, and, does not include multi-layer thin cores, e.g., to avoid elevating the CTE of the package substrate and mitigate warpage issues associated with using multi-layer thin cores. That is, the package substrate is free of multi-layer thin cores.

The term monolithic core, as used herein, refers to a central single insulating layer 102b and metal layers 102c, 102d affixed to first and second (e.g., upper and lower) surfaces 102e, 102f of the insulating layer 102b. Non-limiting examples of the composition of the insulating layer 102b include FR4 fiberglass materials, where FR4 signifies a grade of a flame resistant material which can extinguish by itself after the combustion, as familiar to those skilled in the pertinent arts. Non-limiting example embodiments of the insulating layer 102b composition include sheets of interlacedly weaved fiberglass fibers impregnated with resins such as Bismaleimide/Triazine (BT) epoxy resin to form a prepreg material layer, or an anjinomoto build-up film (ABF) material layer. Non-limiting example embodiments of the metal layers 102c, 102d composition include silver, aluminum, tungsten, copper or alloys thereof. The monolithic core of the disclosure differs from a multi-layer thin core which has individual thin insulating layers, each with a metal layer thereon, laminated together to form a stack corresponding to the multi-layer thin core (e.g., two to five thin cores layers laminated together, each core being 200-250 microns thick).

As further illustrated in FIG. 1A, embodiments of the package substrate 102 can further include insulating layers 116a, 116b, conductive lines or pads (e.g., lines or pads 117a, 117b) located on either or both of the first and second substrate sides and/or via structures 118a, 118b formed though the insulating layers (e.g., first and second side vias 118a, 118b) and vias through the monolithic core (e.g., through-vias 119) to contact the metal layers 102c, 102d and thereby provide connective routing structures as discussed above. In some embodiments, the insulating layers 116a, 116b can be composed of the same material, or similar material, as the material that the central single insulating layer 102b is composed of, e.g., to provide a CTE match (e.g., CTEs of the insulating layer 102b and insulating layers 116a, 116b matching within 10, 5, 1%) to help avoid warpage of the package substrate. However, in other embodiments, the insulating layers 116a, 116b can be composed of different materials, e.g., having a similar CTE match.

As disclosed above, the device module 110 includes one or more silicon-based passive or active device components (e.g., FIG. 1A, device component 115a). The term, silicon-based, as used herein, means that passive or active device components are formed in a silicon layer, e.g., the passive or active device component is formed in a silicon substrate from a silicon wafer as part of a silicon wafer fab for forming ICs, as familiar to one skilled in the pertinent arts. Embodiments of the device module are free of ceramic-based passive or active device components, e.g., capacitors, resistors, inductors or transistors built into a ceramic micro lead-frame chip carrier (MLCC) or similar ceramic carrier structure.

For instance, the silicon-based passive device component can be any integrated circuit component that does not require power from a source of power to perform the passive device's circuit function. Non-limiting examples of passive device components include capacitors, resistors or inductors, or combinations thereof. Some embodiments of the passive device component can include two or more capacitors, resistors or inductors to form an integrated passive device (IPD), as familiar to those skilled in the pertinent arts.

For instance, the silicon-based active device component can be any integrated circuit component with the ability to electrically control electric charge flow in the circuit. Non-limiting examples of active device components include transistors, diodes, rectifiers or other voltage or current controlling device as familiar to those skilled in the pertinent arts. Some embodiments of the active device component can include two or more of transistor, diode or rectifier components to form an integrated active device (ITD), as familiar to those skilled in the pertinent arts.

As noted above, the first and second device module sides 112a, 112a are aligned with the first and second substrate sides 103a, 103b, respectively. Having the module sides 112a, 112b aligned with the sides 103a, 103b of the package substrate 102 can facilitate forming electrical interconnections on the sides between the silicon-based active or passive device components. Having the sides of the device module sides aligned with the sides of the package substrate can facilitate forming the insulating layer on these sides and in the through-cavity 107, as further disclosed herein. As used herein the term, aligned, means that the sides 103a, 103b, of the package substrate 102 and respective sides 112a, 112b of the device module 110, when embedded in the through-cavity 107, are substantially coplanar with each other. For instance, in a direction 125 perpendicular to the first and second substrate side 103a, 103b, the first side 112a of the device module 110 is separated from the first substrate side 103a by a distance 127a of 100, 80, 60, 40, 20, 10 or 5 microns or less, and the second substrate side 103b is separated from the second substrate side 103b by a distance 127b of 100, 80, 60, 40, 20, 10 or 5 microns or less.

In some embodiments, the IC package can have two back-to-back coupled silicon-based device components that together span the thickness of the core. For instance, for the IC package 100 illustrated in FIG. 1B, the package includes the device module 110 includes a first one of the silicon-based passive or active device component 115a and a second one of the silicon-based passive or active device component 115b. The first and second device components (115a, 1105) have a back-to-back coupling to each other. The first side 112a of the device module includes a first set of metal pads 130 connected to the first silicon-based passive or active device component 115a, and the second side 112b of the device module includes a second set of metal pads 132 connected to the second silicon-based passive or active device component 115b. E.g., the metal pads 130, 132 of the device component 115a, 115b can be outwardly situated on the first and second sides 112a, 112b to facilitate providing short or direct electrical connection distances from conductive lines or pads 117a, 117b on the sides of the package substrate to other active or passive device components, or, to a PCB of the IC package, external to the substrate package.

In some such embodiments, the back-to-back coupling between the first and second device components can be or include a coupling layer 134 (e.g., a fusion bond layer or a resin bond layer).

In some such embodiments, e.g., to facilitate providing electrical connectivity to passive or active device components of a SoC device and/or conductive lines on a PCB of the IC package, the first set of metal pads 130 can contact vias (e.g., via 118a) passing through a first insulation layer 116a located on the first module side 112a and the second set of metal pads 132 can contact vias (e.g., via 118b) passing through a second insulation layer 116b located on the second module side 112b.

In any embodiments of the IC package, to facilitate forming electrical connections between the device module 110 metal pads (e.g., pads 130, 132) and the conductive lines or pads 117a, 117b on the sides of the package substrate, the device module 110 can have a thickness 140 value that matches the monolithic core thickness 105 value to within 40, 20, 10 microns.

In any embodiments of the IC package, to facilitate placing the device module 110 into the cavity 107 and filling the cavity 107 with portions of the insulating layers 116a, 116b, the cavity 107 can have a width 142 in a range from 700 μm to 20 mm and the device module 110 has a width 144 in a range from 500 μm to 19.8 mm. In some such embodiments, e.g., the device module 110 has a width 144 that is at least 1, 5, 10 percent smaller than a width 142 of the cavity 107.

As further illustrated in FIGS. 1A and 1B, the first and second insulation layers 116a, 116b can help secure the device module 110 inside the cavity 107. E.g., for a first insulation layer 116a located on the first module side 112a, a portion 116c of the first insulation layer 116a partially fills the through-cavity 107 such that the portion 116c of the first insulation layer 116a contacts first sidewall portions 150a of the device module 110 and first sidewall portions 155a of the cavity 107. E.g., for a second insulation layer 116b located on the second module side 112b, where the portion 116d of the second insulation layer 116b partially fills the through-cavity 107 such that the portion 116d of the second insulation layer 116b contacts second sidewall portions 150b of the device module 110 and second sidewall portions 155b of the cavity 107.

In some embodiments, the IC package can have a silicon-based device component coupled to a dummy silicon spacer layer component which together, span the thickness of the core. For instance, for the IC package 100 illustrated in FIG. 2, the device module 110 of the package 100 includes a first one of the silicon-based passive or active device component 115a, the silicon-based passive or active device component 115a including a first set of metal pads 130 on the first module side 112a, and, a silicon dummy layer component 210 located in the through-cavity 107 and coupled to the silicon-based passive or active device component 115a where a side 212 of the silicon dummy layer component corresponds to the second module side 112b.

The term silicon dummy layer component, as used herein, refers to a silicon layer whose interior is free of passive and active device components, e.g., no capacitor, resistor, inductor or transistor components are present in the silicon dummy layer, and, the dummy silicon layer's thickness 215 (plus any coupling layer 134 between the dummy silicon layer and silicon-based device) is sized to provide the desired spacing so that the device module 110 has an overall thickness 140 to match the monolithic core's thickness 105. E.g., the first and second module sides 112a, 112b are aligned with the first and second substrate sides 103a, 103b such as disclosed in the context of FIGS. 1A-1B.

As further illustrated in FIG. 2, in some such embodiments, to facilitate heat dissipation from the first device 115a to the second substrate side 103b, the side 212 of the silicon dummy layer component can include a second set of metal pads 132 that contact conductive vias 118b passing through a second insulation layer 116b located on the second module side 112b

In some embodiments, the IC package can have a silicon-based device components coupled to a heat sink layer component that together span the thickness of the core. For instance, for the IC package 100 illustrated in FIG. 3, the device module 110 of the package 100 includes a first one of the silicon-based passive or active device component 115a, the silicon-based passive or active device component 115a including a first set of metal pads 130 on the first module side 112a, and, a heat sink layer component 310 located in the through-cavity 107 and coupled to the silicon-based passive or active device component 115a where a side 312 of the heat sink layer component corresponds to the second module side 112b.

The term heat sink layer component, as used herein, refers to a metal layer (e.g., copper, aluminum), and, the heat sink layer's thickness 315 (plus any coupling layer 134 between the dummy silicon layer and silicon-based device) is sized to provide the desired spacing so that the device module 110 has an overall thickness 140 to match the monolithic core's thickness 105. E.g., that the first and second module sides 112a, 112b are aligned with the first and second substrate sides 103a, 103b such as disclosed in the context of FIGS. 1A and 1B.

As further illustrated in FIG. 3, in some such embodiments, to facilitate heat dissipation from the first device 115a to the second substrate side 103b without the need for conductive pads 132 such as shown in FIGS. 1A, 1B and 2, the side 312 of the heat sink layer component can contact conductive vias 118b passing through a second insulation layer 116b located on the second module side 112b.

In some embodiments, the IC package can have two silicon-based device components that are both coupled (e.g., back-to-back coupled) to an internal silicon spacer layer sandwiched in-between the components and which, in combination, span the thickness of the core. For instance, for the IC package 100 illustrated in FIG. 4, the device module 110 of the package 100 includes a first one of the silicon-based passive or active device component 115a, a second one of the silicon-based passive or active device component 115b, and an internal silicon spacer layer component 410 sandwiched in-between the first and second silicon-based passive or active device components 115a, 115b. The first and second device components (115a, 1105) are coupled to opposite first and second sides 412a, 412b of the internal silicon spacer layer component 410. The first side 112a of the device module includes a first set of metal pads 130 connected to the first silicon-based passive or active device component 115a. The second side 112b of the device module includes a second set of metal pads 132 connected to the second silicon-based passive or active device component 115b.

As further illustrated in FIG. 4, in some such embodiments, the first silicon-based passive or active device component 115a can be coupled to the first side 412a of the internal silicon spacer layer component 410 by a first coupling layer 434a (e.g., a first fusion or resin bond layer) and the second silicon-based passive or active device component 115b can be coupled to the second side 412b of the internal silicon spacer layer component 410 by a second coupling layer 434b (e.g., a second fusion or resin bond layer).

From the example embodiments presented herein one skilled in the pertinent arts would appreciate how device module thickness 140 over a broad range could be manufactured to match a range of monolithic core's thickness values 105 so that the first and second module sides 112a, 112b are aligned with the first and second substrate sides 103a, 103b. The first and second module sides 112a, 112b are aligned with the first and second substrate sides 103a, 103b such as disclosed in the context of FIGS. 1A-1B.

In any embodiments of the IC package, as non-limiting examples, if the two silicon-based device components 115a, 115b are formed as part of a 150, 200, 300 or 450 mm diameter silicon wafer fab and the device components are coupled back-to-back then the device modules thickness can be about 1350, 1450, 1550 or 1850, respectively, plus 20 to 40 microns range of thicknesses of metal pads 130, 132 formed on each of the device modules' sides 112a, 112b, to give overall thickness 140 of about 1390 to 1430, 1490 to 1530, 1590 to 1630 or 1890 to 1930, respectively. Further, the sandwiching of the internal silicon spacer layer component 410 between the silicon-based device components 115a, 115b could be used to further increase or adjust the thickness 140. Or, the silicon wafers used to form the device module can be reduced in thickness (e.g., by grinding) to provide a device module thickness in the 800 to 1300 micron range. Or, a single silicon-based device component (115A, FIG. 1) can be fabricated in, e.g., a 300 mm or 400 mm diameter silicon wafer fab to provide a thickness of about 800 or 950 microns or greater thickness when coupled to the silicon dummy layer component 210, the heat sink layer component 310 or internal silicon spacer layer component 410.

In any embodiments of the IC package, the device module 110 can further include one or more through-device vias (e.g., through-silicon vias). Such through-device vias can advantageously provide a simpler, more direct, electrical routing pathway (e.g., though instead of around the device module) between the silicon-based active or passive device component(s) 115a, 115b and the conductive lines or pads 117a, 117b that are connected to other structures of the package 100 (e.g., a SoC or PCB). Alternatively or additionally, in some embodiments, the through-device vias can be part of the passive device component(s) to, e.g., increase the capacitance value of an inductor passive device. Alternatively or additionally, the through-device vias can provide an additional heat dissipation route for the active or passive device component.

For instance, for the IC package 100 illustrated in FIG. 5, the device module 110 of the package 100 can include one or more through-device vias 510 passing through one or more silicon-based passive or active device component (e.g., component 115a in FIG. 1A, or) and contacting metal pads 130, 132 on the first and second module sides 112a, 112b. Similarly, any of the device module 110 embodiments discussed in the context of FIGS. 1B-4 could include one or more through-device vias, e.g., through device components 115a, 115b in FIG. 1B, or device components 115a, 210 in FIG. 2, or device component 115a in FIG. 3, or device components 115a, 115b, 410 in FIG. 4, and contacting the metal pads. As a non-limiting example, the through-device vias 510 can be copper filled vias that are diffusion bonded to the copper metal pads 130, 132.

Another aspect is a method of manufacturing an integrated circuit package. FIGS. 6A-6H presents cross-sectional views of example IC packages, such as any of the example package 100 embodiments disclosed in the context of FIGS. 1A-5, at different stages of manufacture.

With continuing reference to FIGS. 1A-6H throughout, the method includes forming a package substrate 102 including providing a monolithic core 102a (e.g., FIG. 6A), the monolithic core having a first substrate side 103a, a second substrate side 103b opposite the first substrate side, a thickness 105 in a range from 800 to 2000 microns.

Embodiments of forming the package substrate further includes forming a through-cavity 107 in the monolithic core 102a, the through-cavity 107 (E.G., FIG. 6b) passing through the first and second substrate sides 103a, 103b. One skilled in the pertinent arts would be familiar with processes to form a through-cavity such as the through-cavity 107, including, e.g., drilling through-holes in the core 102a, Cu plating, through-hole plugging and patterning the top and bottom Cu layers (e.g., metal layers 102c, 102d) followed by laser or mechanical routing methods to remove portions of the monolithic core to thereby form the through-cavity.

Embodiments of forming the package substrate further include providing a device module 110, the device module having a first module side 112a and a second module side 112b opposite the first module side. Embodiments of providing the device module can further include forming the device module such as further discussed in the context of FIGS. 7A-7E below.

Embodiments of forming the package substrate further include embedding the device module 110 in the through-cavity 107 (e.g., FIG. 6C). When so embedded, the first module side 112a is aligned with the first substrate side 103a, and the second module side 112b is aligned with the second substrate side 103b. The device module 110 includes one or more silicon-based passive or silicon-based active device component (e.g., component 115a) such as discussed in the context of FIGS. 1A-4.

In some embodiments, the embedding of the device module 110 in the through-cavity 107 includes placing the first substrate side 103a of the core substrate 102 with the cavity 107 formed there-through, on a carrier layer 610 (e.g., FIG. 6D), placing the device module 110 in the cavity 107 such that first module side 112a rests on the carrier layer 610, and depositing a first insulation layer 116b on the second substrate side 103b and on the second module side 112b including filling the cavity 107 such that the first insulation layer 116b contacts sidewall portions 150b of the device module 110 and sidewall portions 155b of the cavity 107. As familiar to those skilled in the pertinent arts, in some embodiments the carrier layer can be a sheet of polymer with an optional adhesives thereon so that the carrier can survive the device component placement and other process but still later readily removed.

In some such embodiments, the embedding of the device module 110 in the through-cavity 107 includes removing the carrier layer 610 from the first substrate side 103a and the first module side 112a (e.g., removed by a mechanical or manual peeling action), inverting the core substrate 102 and the device module 110, depositing a second insulation layer 116a on the first substrate side 103a and on the first module side 112a including filling the cavity 107 such that the second insulation layer 116a contacts sidewall portions 150a of the device module 110 and sidewall portions 155a of the cavity to hold the device module in the cavity.

Embodiments of forming the package substrate can further include forming metal lines or pads 117a, 117b and vias 118a, 118b though the first and second insulating layers 116a, 116b where some of the metal lines and via are in contact with first and second sets of metal pads 130, 132 on the first and second module sides 112a, 112b.

FIGS. 7A-7E present cross-sectional views of an example device module having one or more silicon-based device components, such as in the example module embodiments disclosed in the context of FIGS. 1-5, at different stages of device formation as part of the manufacture of the IC package.

Some embodiments of forming the device module 110 can include providing a silicon wafer 710a, forming the silicon-based passive or active device component 115a in the silicon wafers 710a, where the silicon-based passive or active device component 115a includes a first set of metal pads 130 on the first module side 112a and dicing the first silicon wafer to form the device module 110.

Some such embodiments can further include providing a second silicon wafer 710b, forming a second one of the silicon-based passive or active device component 115b in the second silicon wafer 710b, where the second silicon-based passive or active device component 115b including a second set of metal pads 132 on the first module side 112a, coupling the first and second silicon wafers 710a, 710b together to form a back-to-back coupled wafer pair 712 and dicing the coupled wafer pair 712 to form the device module 110.

One skilled in the pertinent arts would be familiar with various processes to couple wafers or dies together. Non-limiting examples include: putting a resin on the wafer surfaces and then holding the wafers together until a resin bond (e.g., resulting in any of coupling layers 134, 434a, 434b) is formed, coupling via solder bonds formed on the metal pads of two wafer or dies, or, bonding metal (e.g., Cu) pads on the two wafers or dies via heat and pressure to form a fusion bond (e.g., resulting in any of coupling layers 134, 434a, 434b).

Alternatively, some such embodiments can further include providing a second dummy silicon wafer 710b, where the second dummy silicon wafer is free of passive or active device components, coupling the first and second silicon wafers 710a, 710b together to form a coupled wafer pair 714, and dicing the coupled wafer pair 714 to form the device module 110. Some such embodiment can further include providing a third silicon wafer 710c, where the third silicon wafer 710c is free of passive or active device components, coupling the first silicon wafers 710a, to one side of the third silicon wafer 710c and coupling the second silicon wafer 710b to an opposite side of the third silicon wafer 710c, where the first, second and third wafers form a three-layer silicon stack 716, and then dicing the three-layer silicon stack 716 to form the device module 110.

As another alternative, some embodiments can further include providing a heat sink layer 720, coupling the first silicon wafer 710a, to the heat sink layer 720 to form a wafer-heat sink coupled pair 718, and dicing the wafer-heat sink coupled pair 718, to form the device module 110. One skilled in the pertinent arts would be familiar with process to couple the heat sink layer to the first silicon wafer. As non-limiting examples, embodiments of the heat sink layer can be directly soldered to the silicon wafer by first metallizing the silicon surface followed by applying a solder material between the silicon and the heat sink layer, the silicon and heat sink layers can be bonded using a polymer-based thermal interface materials, or the heat sink layer can be directly depositing on silicon by plating or vapor deposition.

Any embodiments of the method of forming the device module 110 can further include optional grinding of the first and/or second and/or third silicon wafer 710a, 710b, 710c to form reduced-thickness silicon wafers 720a, 720b, 720c, 720d, such that the desired overall thickness 140 of the device module will match the thickness 107 of the monolithic core, so that the first module side 112a is aligned with the first substrate side 103a and so that the second module side 112b is aligned with the second substrate side 103b, such as disclosed herein. E.g., the back-to-back coupled wafer pair 712 can be back-to-back coupled first and second reduced-thickness silicon wafers 720a, 720b, the coupled wafer pair 714 can be coupled first reduced-thickness silicon wafer 720a and second reduced-thickness dummy silicon wafer 720c, the three-layer silicon stack 716 can be coupled first reduced-thickness silicon wafer 720a, third reduced-thickness silicon wafer 710c and second reduced-thickness silicon wafer 720b. Similarly, the wafer-heat sink coupled pair 718 can be the first reduced-thickness silicon wafer 720a coupled to the heat sink layer 725. In other embodiments, however, the original thickness wafer 710a, 710b, 710c can be used to form the device module having a single diced wafer (e.g., wafer 710a with the silicon-based passive or silicon-based active device component 115a formed therein after dicing), or, having the various coupled pairs 712, 714, three-layer silicon stack 716 or wafer-heat sink coupled pair 718.

Any embodiments of the method of forming the device module 110 can further include forming one or more through-device vias 510, e.g., in the first and/or second and/or third silicon wafer 710a, 710b, 710c or their reduced-thickness silicon wafer 720a, 720b, 720c counterparts or the various coupled pairs 712, 714, three-layer silicon stack 716 or wafer-heat sink coupled pair 718.

FIG. 8 presents another example embodiment of the integrated circuit package 100 including any embodiments of the package substrate 102 and the device module 110 disclosed in the context of FIGS. 1-5 and made by any embodiments of the method disclosed in the context of FIGS. 6A-7E.

As illustrated, the package 100 can further include a SoC package 805 (e.g., including one or more HBM 810 and CPUs and/or GPUs in an application specific integrated circuit, ASIC 815) and a PCB 820 electrically connected to the device module 110. E.g., the conductive layers, lines, pads and vias of the package substrate (e.g., FIGS. 1-5, layers, lines or pads 102c, 102d, 117a, 117b, and/or vias 118a, 118b, 119 and/or pads 130, 132 and vias 510) of the device module and solder ball grid arrays (e.g., BGAs 825, 830, 835) can interconnect the SoC package 805 or PCB 820 to each other or to external circuits, as familiar to one skilled in the pertinent arts. For instance, in some embodiments, the integrated circuit package 100 can be part of a computer graphics processing ASIC such as a graphics processing Chip-on-Wafer-on-Substrate.

Those skilled in the art to which this application relates will appreciate that other and further additions, deletions, substitutions and modifications may be made to the described embodiments.

What is claimed is:

1. An integrated circuit package, comprising:
a package substrate including a monolithic core, the monolithic core having a first substrate side, a second substrate side opposite the first substrate side, a thickness in a range from 800 to 2000 microns and a through-cavity that passes through the first and second substrate sides; and
a device module, the device module having a first module side and a second module side opposite the first module side, wherein:
the device module is embedded in the through-cavity,
the first module side is aligned with the first substrate side,
the second module side is aligned with the second substrate side,
and
the device module includes one or more silicon-based passive or silicon-based active device component.

2. The package of claim 1, wherein the device module includes a first one of the silicon-based passive or active device component and a second one of the silicon-based passive or active device component, wherein:
the first and second device components have a back-to-back coupling to each other,
the first side of the device module includes a first set of metal pads connected to the first silicon-based passive or active device component, and
the second side of the device module includes a second set of metal pads connected to the second silicon-based passive or active device component.

3. The package of claim 2, wherein the back-to-back coupling includes a coupling layer.

4. The package of claim 2, wherein the first set of metal pads contact vias passing through a first insulation layer located on the first module side and the second set of metal pads contact vias passing through a second insulation layer located on the second module side.

5. The package of claim 1, wherein the device module has a thickness value that matches the monolithic core thickness value to within 40, 20, 10 microns.

6. The package of claim 1, further including:
a first insulation layer located on the first module side, wherein a portion of the first insulation layer partially fills the through-cavity such that the portion of the first insulation layer contacts first sidewall portions of the device module and first sidewall portions of the cavity, and
a second insulation layer located on the second module side, wherein the portion of the second insulation layer partially fills the through-cavity such that the portion of the second insulation layer contacts second sidewall portions of the device module and second sidewall portions of the cavity.

7. The package of claim 1, wherein the device module includes:
a first one of the silicon-based passive or active device component, the silicon-based passive or active device component including a first set of metal pads on the first module side, and
a silicon dummy layer component located in the through-cavity and coupled to the silicon-based passive or active device component wherein a side of the silicon dummy layer component corresponds to the second module side.

8. The package of claim 7, wherein the side of the silicon dummy layer component includes a second set of metal pads that contact conductive vias passing through a second insulation layer located on the second module side.

9. The package of claim 1, wherein the device module includes:
a first one of the silicon-based passive or active device component, the silicon-based passive or active device component including a first set of metal pads on the first module side, and
a heat sink layer component located in the through-cavity and coupled to the silicon-based passive or active device component wherein a side of the heat sink layer component corresponds to the second module side.

10. The package of claim 9, wherein the side of the heat sink layer component contacts conductive vias passing through a second insulation layer located on the second module side.

11. The package of claim 1, wherein the device module includes a first one of the silicon-based passive or active device component, a second one of the silicon-based passive or active device component, and an internal silicon spacer layer component sandwiched in-between the first and second silicon-based passive or active device components, wherein:
the first and second device components are coupled to opposite first and second sides of the internal silicon spacer layer component,
the first side of the device module includes a first set of metal pads connected to the first silicon-based passive or active device component, and
the second side of the device module includes a second set of metal pads connected to the second silicon-based passive or active device component.

12. The package of claim 11, wherein the first silicon-based passive or active device component is coupled to the first side of the internal silicon spacer layer component by a first coupling layer and the second silicon-based passive or active device component is coupled to the second side of the internal silicon spacer layer component by a second coupling layer.

13. The package of claim 1, wherein the device module further includes one or more through-device vias passing through the one or more silicon-based passive or active device component and contacting metal pads on the first and second module sides.

14. The package of claim 1, further including a system-on-chip package and printed circuit board electrically connected to the device module.

15. A method of manufacturing an integrated circuit package, comprising:
forming a package substrate including:
providing a monolithic core, the monolithic core having a first substrate side, a second substrate side opposite the first substrate side, a thickness in a range from 800 to 2000 microns,
forming a through-cavity in the monolithic core, the through-cavity passing through the first and second substrate sides,
providing a device module, the device module having a first module side and a second module side opposite the first module side, and
embedding the device module in the through-cavity, wherein:
the first module side is aligned with the first substrate side,
the second module side is aligned with the second substrate side,
and
the device module includes one or more silicon-based passive or silicon-based active device component.

16. The method of claim 15, wherein the embedding of the device module in the through-cavity includes:
placing the first substrate side of the core substrate with the cavity formed there-through on a carrier layer,
placing the device module in the cavity such that first module side rests on the carrier layer, and
depositing a first insulation layer on the second substrate side and on the second module side including filling the cavity such that the first insulation layer contacts sidewall portions of the device module and sidewall portions of the cavity.

17. The method of claim 16, wherein the embedding of the device module in the through-cavity includes:
removing the carrier layer from the first substrate side and the first module side;
inverting the core substrate and the device module;
depositing a second insulation layer on the first substrate side and on the first module side including filling the cavity such that the second insulation layer contacts sidewall portions of the device module and sidewall portions of the cavity to hold the device module in the cavity.

18. The method of claim 15, further including forming metal lines and vias though the first and second insulating layers, wherein some of the metal lines and via are in contact with first and second sets of metal pads on the first and second module sides.

19. The method of claim 15, wherein the providing of the device module further including forming the device module, including:
providing a silicon wafer;
forming the silicon-based passive or active device component in the silicon wafers, wherein the silicon-based passive or active device component including a first set of metal pads on the first module side; and
dicing the first silicon wafer to form the device module.

20. The method of claim 19, further including:
providing a second silicon wafer,
forming a second one of the silicon-based passive or active device component in the second silicon wafer, wherein the second silicon-based passive or active device component including a second set of metal pads on the first module side;
coupling the first and second silicon wafers together to form a back-to-back coupled wafer pair, and
dicing the back-to-back coupled wafer pair to form the device module.
